(19) United States
(12) Patent Application Publication
(10) Pub. No.: US 2026/0068622 A1
(43) Pub. Date: Mar. 5, 2026

(54) SEMICONDUCTOR DEVICE WITH BACKSIDE POWER DELIVERY

(71) Applicant: AP MEMORY TECHNOLOGY CORPORATION, Zhubei City (TW)

(72) Inventor: Wenliang CHEN, Zhubei City (TW)

(73) Assignee: AP MEMORY TECHNOLOGY CORPORATION, Zhubei City (TW)

(21) Appl. No.: 19/003,510

(22) Filed: Dec. 27, 2024

Related U.S. Application Data
(60) Provisional application No. 63/690,909, filed on Sep. 5, 2024.

(51) Int. Cl. H01L 23/48; H01L 23/00; H01L 25/07; H10D 1/20

(52) U.S. Cl. CPC H01L 23/481; H10D 1/20

(57) ABSTRACT

A semiconductor device and a semiconductor package comprising the semiconductor device are provided. The semiconductor device comprises a first semiconductor die having a front side and a backside opposite to the front side and comprising first active components disposed adjacent to the front side of the first semiconductor die. The semiconductor device also comprises a second semiconductor die having a first side bonded to the backside of the first semiconductor die and a second side opposite to the first side. The second semiconductor die comprises passive components that are configured to manage a power delivery to the first semiconductor die.

### CROSS REFERENCE TO RELATED APPLICATIONS

This application claims the benefit of U.S. Provisional Application No. 63/690,909, filed Sep. 5, 2024, the entirety of which is incorporated by reference herein.

### BACKGROUND

### Technical Field

The present application relates to a semiconductor technology, and in particular to a semiconductor device with power delivery that is capable of minimizing parasitic effects.

### Description of the Related Art

Various semiconductor chips/dies require power to function, such as high-performance-computing (HPC) chips/dies. Therefore, there is a need for improved power delivery for these semiconductor chips/dies.

Although existing semiconductor devices with power delivery in the semiconductor chips/dies are well known and generally adequate for their intended purposes, they have not been satisfactory in all respects. For example, these semiconductor devices may comprise non-ideal arrangement or configuration that suffers from parasitic losses to reduce power delivery performance.

### BRIEF SUMMARY

In some embodiments, a semiconductor device is provided. The semiconductor device comprises a first semiconductor die having a front side and a backside opposite to the front side and comprising first active components disposed adjacent to the front side of the first semiconductor die. The semiconductor device also comprises a second semiconductor die having a first side bonded to the backside of the first semiconductor die and a second side opposite to the first side. The second semiconductor die comprises passive components that are configured to manage a power delivery to the first semiconductor die.

In some embodiments, a semiconductor device is provided. The semiconductor device comprises a first semiconductor die having a front side and a backside opposite to the front side and comprising a first processing unit and a second processing unit adjacent to the front side. The semiconductor device also comprises a second semiconductor die having a first side bonded to the first semiconductor die and a second side opposite to the first side and comprising a first power conversion unit and a second power conversion unit. The first power conversion unit and the second power conversion unit are configured to respectively receive a first input voltage and a second input voltage from the second side of the second semiconductor die and respectively provide a first output voltage to the first processing unit and a second output voltage to the second processing unit.

In some embodiments, a semiconductor package is provided. The semiconductor package comprises a package substrate comprising a power input pad and a signal input/output pad formed on a top surface of the package substrate. The semiconductor package also comprises a first conductive connector electrically coupled to the power input pad and a second conductive connector electrically coupled to the signal input/output pad. The semiconductor package further comprises a stack structure comprising a top semiconductor die and a bottom semiconductor die. The top semiconductor die comprises first transistors therein and has a front side and a backside opposite to the front side. The bottom semiconductor die comprises capacitors therein. The bottom semiconductor die has a first side bonded to the backside of the top semiconductor die and a second side opposite to the first side. The second side of the bottom semiconductor die is electrically coupled to the power input pad of the package substrate via the first conductive connector.

### BRIEF DESCRIPTION OF THE DRAWINGS

FIG. 1 is a cross-sectional view of a semiconductor package in accordance with some embodiments.

FIG. 2 is a cross-sectional view of a semiconductor device with a power delivery in the semiconductor package shown in FIG. 1 in accordance with some embodiments.

FIG. 3 is a cross-sectional view of a semiconductor package in accordance with some embodiments.

FIG. 4 is a cross-sectional view of a semiconductor device with a power delivery in the semiconductor package shown in FIG. 3 in accordance with some embodiments.

FIG. 5A is a schematic block diagram illustrating a passive circuit in a semiconductor die in accordance with some embodiments.

FIG. 5B is a schematic block diagram illustrating a power conversion circuit in a semiconductor die in accordance with some embodiments.

FIG. 6 is a cross-sectional view of a semiconductor device with a power delivery in accordance with some embodiments.

FIG. 7 is a cross-sectional view of a semiconductor device with a power delivery in accordance with some embodiments.

FIG. 8 is a schematic block diagram illustrating a semiconductor device with a power delivery in accordance with some embodiments.

FIG. 9A is a cross-sectional view of exemplary 3D cylinder-type capacitors in accordance with some embodiments.

FIG. 9B is a cross-sectional view of exemplary 3D crown-type capacitors in accordance with some embodiments.

FIG. 10 is a cross-sectional view of a semiconductor device with a power delivery in accordance with some embodiments.

FIG. 11 is a cross-sectional view of a semiconductor device with a power delivery in accordance with some embodiments.

### DETAILED DESCRIPTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed.

In the manufacture of semiconductor devices, a semiconductor wafer having semiconductor dies is formed. The semiconductor die comprises hundreds or thousands of transistors that perform one or more electrical functions. Each semiconductor die singulated from the semiconductor wafer typically performs the same electrical function and has a front side (which is sometimes referred to as active side) containing the transistors. Each individual die is then encapsulated in a semiconductor package for structural support and/or environmental isolation.

A semiconductor die generally comprises a substrate. The substrate comprises a front side surface (which is sometimes referred to as active surface) having semiconductor transistors disposed thereon/therein, and a backside surface formed with bulk semiconductor material, e.g., silicon. The front side surface of the substrate is formed by a variety of semiconductor processes, comprising deposition, patterning, doping, heat treatment and planarization. In the deposition process, various materials are grown or deposited on the substrate by, for example, chemical vapor deposition, atomic layer deposition, evaporation, and sputtering thermal oxidation, nitridation, or the like. In the patterning process, photolithography and etching process (e.g., dry etching or wet etching) are performed to remove away undesired material to form specific structures. After the formation of semiconductor transistors adjacent to the front side surface of the substrate, a middle-end-of-line (MEOL) layer or/and a back-end-of-line (BEOL) layer are formed above the semiconductor transistors and the front side surface of the substrate. In other words, the BEOL layer is adjacent to the front side surface of the substrate and distal to the backside surface of the substrate.

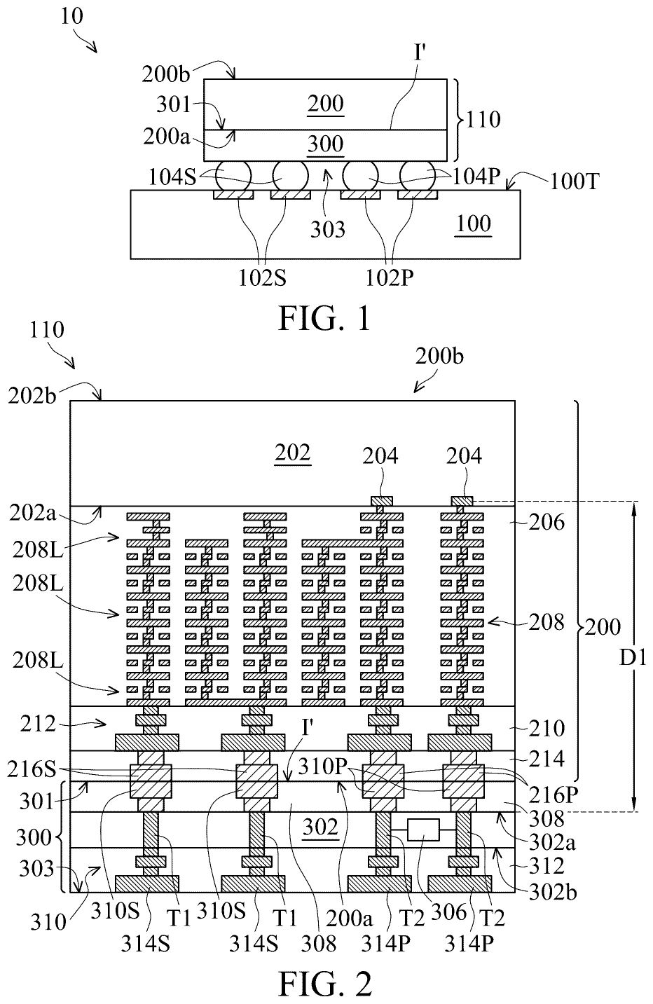

Referring to FIGS. 1 and 2, FIG. 1 is a cross-sectional view of a semiconductor package 10 in accordance with some embodiments, and FIG. 2 is a cross-sectional view of a semiconductor device 110 with a power delivery in the semiconductor package 10 shown in FIG. 1 in accordance with some embodiments. As shown in FIG. 1, in some embodiments, the semiconductor package 10 comprises a package substrate 100, such as a package board or an interposer. Several pads are formed on the top surface 100T of the package substrate 100. In some embodiments, those pads may comprise one or more signal input/output pads, one or more power input pads, and one or more ground pads. In order to simplify the diagram herein, only two signal input/output pads 102S (or referred to as signal pads) and two power input pads 102P (or referred to as power pads, including power input pads and ground pads) are depicted.

In some embodiments, the semiconductor package 10 further comprises a semiconductor device 110 formed over the substrate 100 and conductive connectors (such as first conductive connectors 104S and second conductive connectors 104P) formed between the semiconductor device 110 and the substrate 100. In some embodiments, the first conductive connectors and the second conductive connectors comprise solder balls, bumps or conductive pillars and are employed to mount the semiconductor device 110 onto the package substrate 100. For example, the first conductive connectors 104S and the second conductive connectors 104P may comprise solder balls, as shown in FIG. 1. In order to simplify the diagram herein, only two first conductive connectors 104S and two second conductive connectors 104P are depicted. The first conductive connectors 104S and the second conductive connectors 104P are correspondingly bonded to the signal input/output pads 102S and power input pads 102P, respectively.

In some embodiments, the semiconductor device 110 (which is also referred to as die stack structure herein) comprises a first semiconductor die 200 (which is also referred to top semiconductor die herein) and a second semiconductor die 300 (which is also referred to bottom semiconductor die herein) stacked below the first semiconductor die 200. In some embodiments, the first semiconductor die 200 is a logic circuit die, an analog circuit die or a memory die that contains one or more active components 204 (e.g., transistors) (as shown in FIG. 2) formed therein. In some embodiments, the first semiconductor die 200 comprises a machine learning processor or a deep learning processor that contains those active components. In some other embodiments, the active components 204 in the first semiconductor die 200 may be the transistors to control or to switch the advanced memory device, such as but not limited to the switch transistors for advanced dynamic random access memory (DRAM) or high-bandwidth memory (HBM).

Unlike the first semiconductor die 200, the second semiconductor die 300 is a passive circuit die that comprises a passive circuit 306 (as shown in FIG. 2) containing passive components (e.g., capacitors and/or inductors) (not shown). In some other embodiments, the second semiconductor die 300 is a power conversion circuit die that contains one or more passive components electrically coupled to one or more active components in the second semiconductor die 300. In some embodiments, over 30% of the die footprint area of the second semiconductor die 300 is used for forming the passive components. In some embodiments, over 80% of the die footprint area of the second semiconductor die 300 is used for forming the passive components.

In some embodiments, the capacitors in the passive circuit die or the power conversion circuit die are 3D cylinder-type or crown-type capacitors which are compatibly formed with the semiconductor process. In some embodiments, the 3D cylinder-type or crown-type capacitors have a smaller size and larger capacitance than traditional MLCC (Multilayer ceramic capacitor) capacitors. Furthermore, the capacitance of the cylinder-type or crown-type capacitors is larger than the conventional semiconductor capacitors such as planar MIM or MIS type capacitors.

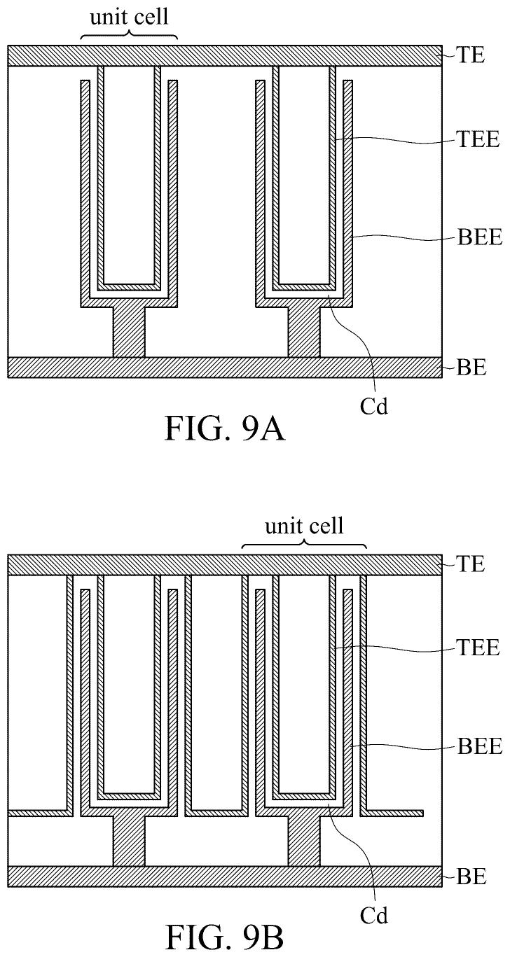

As shown in FIGS. 9A and 9B, for example but not limitation, which illustrates exemplary cross-sectional views of 3D cylinder-type (or called concave-type) and crown-type capacitors, respectively. One unit cell of the 3D cylinder-type or crown-type capacitors may comprise a top electrode TE, a bottom electrode BE, a top extending portion TEE electrically connected to the top electrode TE and extends toward the bottom electrode BE, a bottom extending portion BEE electrically connected to the bottom electrode BE and laterally surround the top extending portion TEE, and a dielectric film Cd, such as a high-K film (e.g., a Lanthanum oxide, Hafnium oxide or Zirconium oxide film) formed between the top extending portion TEE and the bottom extending portion BEE. The 3D cylinder-type or crown-type capacitors include about 10 to about 100 times larger capacitance than conventional semiconductor capacitors in the unit area. Furthermore, comparing with the any possible capacitors in the logic die, the 3D cylinder-type or crown-type capacitors includes over 100 times larger capacitance in unit area than the parasitic capacitance in unit area. Similarly, the 3D cylinder-type or crown-type capacitors includes over 100 times larger capacitance in the unit area than the conventional semiconductor capacitor (e.g., planar MIM type capacitor or MIS type capacitor) embedded in the logic die. In some embodiments, the unit cells of the 3D cylinder-type or crown-type capacitors can be arranged in any suitable array shape, such as a rectangular array or a hexagonal array, in a plan view.

The first semiconductor die 200 has a front side 200a and a backside 200b opposite to the front side 200a. In some embodiments, the first semiconductor die 200 is flipped, so that the front side 200a faces toward the second semiconductor die 300. Moreover, the second semiconductor die 300 has a first side 301 bonded to the front side 200a of the first semiconductor die 200 and a second side 303 opposite to the first side 301. The first conductive connectors 104S and the second conductive connectors 104P are bonded to the second side 303 of the second semiconductor die 300, so that the semiconductor device 110 are mounted onto the package substrate 100 via those first and second conductive connectors 104S and 104P.

FIG. 2 shows the details of the first semiconductor die 200 and the second semiconductor die 300 in the semiconductor device 110 in accordance with some embodiments. More specifically, the first semiconductor die 200 comprises a substrate 202 having a front side surface (which is sometimes referred to as active surface) 202a and a backside surface 202b corresponding to the front side 200a and the backside 200b of the first semiconductor die 200, respectively, so that the front side surface 202a is opposite to the backside surface 202b. Typically, the active components 204 (e.g., transistors) in the first semiconductor die 200 are formed adjacent to the front side surface 202a of the substrate 202.

In some embodiments, the first semiconductor die 200 further comprises insulating layers 206, 210, and 214 that are successively formed over the front side surface 202a. The insulating layer 206 comprises an interlayer dielectric (ILD) layer and one or more inter-metal dielectric (IMD) layers. In order to simplify the diagram, only a single layer (i.e., the insulating layer 206) is depicted. A multi-layer interconnect structure 208 are formed in the insulating layer 206 that are electrically coupled to the active components 204. Typically, the multi-layer interconnect structure 208 comprises one or more stacks of metal layers and one or more conductive vias in the insulating layer 206. Those metal layers, can be referred as MEOL and/or BEOL, in each stack are vertically arranged and electrically coupled to each other by the conductive vias between two adjacent metal layers. The insulating layer 210 comprises a redistribution layer (RDL) structure 212 formed therein. The insulating layer 214 may be referred to as a passivation layer. The insulating layer 214 may be made of inorganic or organic materials. Bonding pads may be formed in the insulating layer 214. Those bonding pads are electrically coupled to the RDL structure 212 by, for example, conductive vias. In order to simplify the diagram herein, only two signal bonding pads 216S and two power bonding pads 216P are depicted.

The second semiconductor die 300 comprises a device layer 302 having a first surface 302a and a second surface 302b corresponding to the first side 301 and the second side 303 of the second semiconductor die 300, respectively, so that the first surface 302a is opposite to the second surface 302b. Through-substrate vias (TSVs) T1 and T2 and the passive circuit 306 containing passive components are formed in the device layer 302, in which the passive circuit 306 can be electrically to exterior circuits through those TSVs T1 and T2.

In some embodiments, the second semiconductor die 300 further comprises an insulating layer 308 formed over the first surface 302a of the device layer 302. The insulating layer 308 may be referred to as a passivation layer of the second semiconductor die 300. The insulating layer 308 may be made of inorganic or organic materials. Bonding pads may be formed in the insulating layer 308. Those bonding pads are electrically coupled to the TSVs T1 and T2 formed in the device layer 302. For the sake of brevity, only two signal bonding pads 310S and two power bonding pads 310P are depicted.

In some embodiments, the second semiconductor die 300 further comprises an insulating layer 312 formed over the second surface 302b of the substrate 302. An RDL structure 310 with signal and power pads is formed in the insulating layer 312. The RDL structure 310 with signal and power pads (such as signal input/output pads 314S and power input pads 314P) is electrically coupled to those signal bonding pads 310S and power bonding pads 310P in the insulating layer 308 through the TSVs T1 and T2 formed in the device layer 302.

In some embodiments, the signal input/output pads 314S and the power input pads 314P are correspondingly bonded to the first conductive connectors 104S and the second conductive connectors 104P, respectively. As a result, a power source can provide a voltage from the power input pads 102P of the package substrate 100 to the first semiconductor die 200 via the second conductive connectors 104P, the power input pads 314P, the TSVs T2 and the passive circuit 306 formed in the substrate 302, and the power bonding pads 310P. Moreover, a signal source can be provided from the first semiconductor die 200 to the package substrate 100 or provided from the package substrate 100 to the first semiconductor die 200 via the first conductive connectors 104S, the signal input/output pads 314S, the TSVs T1 formed in the substrate 302, and the signal bonding pads 310S.

In some embodiments, the signal input/output pads 314S and/or the power input pads 314P have a thickness that is greater than a thickness of each one of metal layers 208L in the multi-layer interconnect structure 208. In some embodiments, signal input/output pads 314S and/or the power input pads 314P protrude over the insulating layer 310.

In some embodiments, the flipped first semiconductor die 200 is bonded to the second semiconductor die 300 by a hybrid bonding process, so as to form a hybrid bonding interface I′ between the front side 200a of the first semiconductor die 200 and the first side 301 of the second semiconductor die 300. The hybrid bonding involves at least two types of bonding, comprising metal-to-metal bonding and non-metal-to-non-metal bonding (or dielectric-to-dielectric bonding). In those cases, the metal-to-metal bonding involves the signal bonding pads 310S in direct contact with the signal bonding pads 216S and the power bonding pads 310P in direct contact with the power bonding pads 216P. Moreover, the dielectric-to-dielectric bonding involves the insulating layer 308 that is in direct contact and/or covalently bonded with the insulating layer 214. The bonding process is not limited to the above-recited examples, and the other suitable bonding methods can also be applied.

The passive circuit 306 can function as voltage regulator or voltage converter between the power source and the point of load (i.e., the active component 204). In the semiconductor device 110 with a power delivery, parasitic losses between the point of load in the first semiconductor die 200 and the passive circuit 306 in the second semiconductor die 300 may be varied with the distance D1 between the active component 204 and the second semiconductor die 300 comprising the passive circuit 306. Therefore, the power delivery performance can be enhanced by reducing the distance D1. As shown in FIG. 2, since the passive circuit 306 is integrated in the second semiconductor die 300 that is bonded to the first semiconductor die 200 comprising the active component 204, the distance D1 can be shorter than the cases where the passive circuit is embedded in or disposed on the package board or the interposer substrate and the power transmission path need to cross the long distance in the package board or the interposer substrate (e.g., package substrate 100).

In this embodiment, the passive circuit 306 is configured to manage the power delivery to the first semiconductor die 200. The passive circuit 306 is configured to receive an input power from the power source, then provide a regulated or converted power delivery to the point of load in the first semiconductor die 200. In some embodiments, the regulated or converted power delivery can be served as a stable power for the operation by the point of load in the first semiconductor die 200.

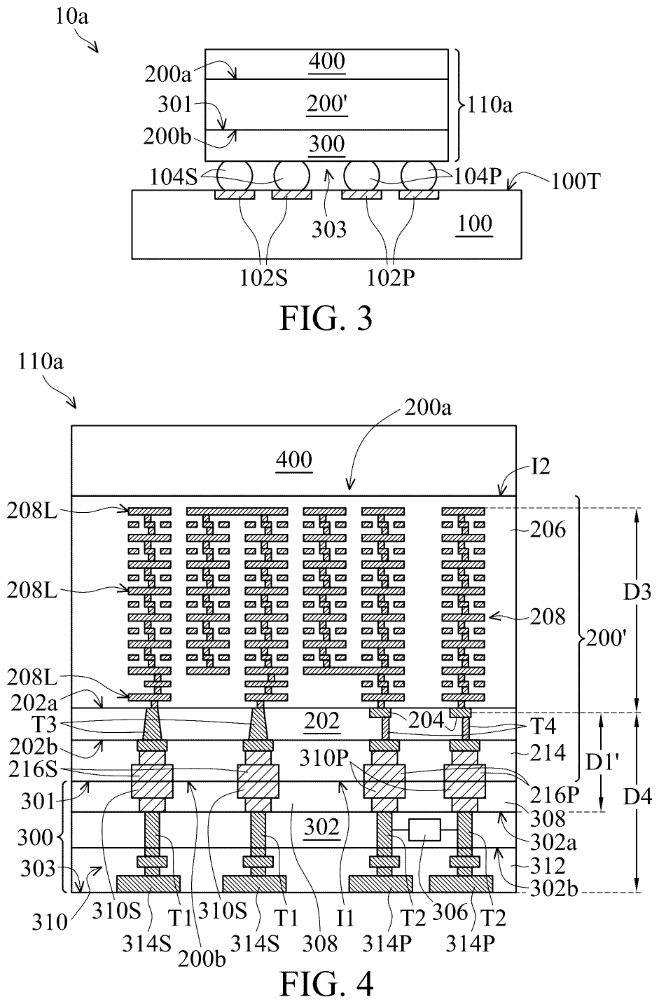

Referring to FIGS. 3 and 4, FIG. 3 is a cross-sectional view of a semiconductor package 10a in accordance with some embodiments, and FIG. 4 is a cross-sectional view of a semiconductor device 110a with a power delivery in the semiconductor package 10a shown in FIG. 3 in accordance with some embodiments. Elements in FIGS. 3 and 4 that are similar to those in FIGS. 1 and 2 are labeled with the same reference numbers as in FIGS. 1 and 2 and may not be described again. In some embodiments, the semiconductor package 10a shown in FIGS. 3 and 4 is similar to the semiconductor package 10 shown in FIGS. 1 and 2. More specifically, the semiconductor package 10a comprises a package substrate 100, a semiconductor device 110a formed over the package substrate 100, and conductive connectors (such as first conductive connectors 104S and second conductive connectors 104P) formed between the semiconductor device 110a and the package substrate 100. However, the semiconductor device 110a has a configuration and/or structure different than the configuration and/or structure of the semiconductor device 110 shown in FIGS. 1 and 2.

As shown in FIG. 3, the semiconductor device 110a comprises a first semiconductor die 200′ (which is also referred to top semiconductor die herein), a second semiconductor die 300 (which is also referred to bottom semiconductor die herein) stacked below the first semiconductor die 200′, and a capping substrate 400 stacked above the first semiconductor die 200′. Similar to the first semiconductor die 200, the first semiconductor die 200′ is a logic circuit die, an analog circuit die or a memory die that contains one or more active components 204 formed therein. For example, the first semiconductor die 200′ comprises a machine learning processor or a deep learning processor that contains those active components.

Unlike the first semiconductor die 200, the first semiconductor die 200′ is not flipped in the configuration of the semiconductor device 110a, so that the backside 200b of the first semiconductor die 200′ faces toward the second semiconductor die 300 and the front side 200a of the first semiconductor die 200′ faces toward the capping substrate 400.

In some embodiments, the first side 301 of the second semiconductor die 300 is bonded to the backside 200b of the first semiconductor die 200′ and the second side 303 opposite to the first side 301 of the first semiconductor die 200′ is bonded to the top surface 100T of the package substrate 100 via the first and second conductive connectors 104S and 104P, as shown in FIG. 3.

FIG. 4 shows more details of the first semiconductor die 200′ and the second semiconductor die 300 in the semiconductor device 110a in accordance with some embodiments. More specifically, the first semiconductor die 200′ comprises a substrate 202 that has a front side surface 202a and a backside surface 202b, and comprises active components 204 formed adjacent to the front side surface 202a of the substrate 202. In some embodiments, the first semiconductor die 200′ further comprises the insulating layer 206 (which comprises a multi-layer interconnect structure 208 formed therein and electrically coupled to the active components 204) and the insulating layer 214 (which comprises signal bonding pads 216S and power bonding pads 216P formed therein and electrically coupled to the active components 204). The insulating layers 206 and 214 are formed over the front side surface 202a and the backside surface 202b of the substrate 202, respectively.

In some embodiments, the substrate 202 comprises TSVs T3 and T4 formed therein, in which the active components 204 and the multi-layer interconnect structure 208 can be electrically to the TSVs T1 and T2 in the second semiconductor die 300 through those TSVs T3 and T4. In some embodiments, the TSVs T3 are electrically coupled to the metal layers 208L in the multi-layer interconnect structure 208. The TSVs T4 are electrically coupled to the active components 204. For the sake of brevity, only two TSVs T3 and two TSVs T4 are depicted. In some embodiments, the Through-substrate vias (TSVs) may penetrate through some dielectric layers (e.g., silicon oxide layer, silicon nitride layer, etc) formed during the fabrication of the first semiconductor die 200′ and the second semiconductor die 300. Therefore, the TSVs T1, T2, T3 and T4 may comprise different types of connectors, such as through-silicon vias, through-oxide vias (TOV), through-glass via (TGV) or through-dielectric vias (TDV).

In some embodiments, those TSVs T3 and T4 are formed in the substrate 202 prior to the bonding process. As shown in FIG. 4, the TSVs T3 are connected to the lowermost ones of the metal layers 208L in the multi-layer interconnect structure 208, which are adjacent to the active components 204. Compared to the embodiment shown in FIG. 2 where signals transmit through the metal layer 208L in each level of the multi-layer interconnect structure 208, some signals from the active components 204 can be transmitted through only few metal layers 208L in the lower levels of the multi-layer interconnect structure 208. As a result, the transmitting speed in the embodiment of FIG. 4 is faster than the embodiment of FIG. 2.

In some embodiments, the first semiconductor die 200′ is bonded to the second semiconductor die 300 by a hybrid bonding process, so as to form a hybrid bonding interface I1 between the backside 200b of the first semiconductor die 200′ and the first side 301 of the second semiconductor die 300. As a result, the signal bonding pads 310S in direct contact with the signal bonding pads 216S and the power bonding pads 310P in direct contact with the power bonding pads 216P. Moreover, the insulating layer 308 is in direct contact and/or covalently bonded with the insulating layer 214. In some embodiments, the front side 200a of the first semiconductor die 200′ is attached to the capping substrate 400, so as to form an interface I2 between the top surface of the insulating layer 206 (i.e., the front side 200a of the first semiconductor die 200′), and the bottom surface of the capping substrate 400, as shown in FIGS. 3 and 4. In some of the embodiments, the capping substrate 400 is a carrier substrate fabricated by Si substrate, glass substrate, or other suitable materials. In some embodiments, the capping substrate 400 is free of conductors, active components and passive components.

In such a configuration of the semiconductor device 110a, a front side distance D3 measured from the uppermost one of the metal layers 208L in the multi-layer interconnect structure 208 to the active component 204 is in a range from about 5 μm to about 15 μm, in accordance with some embodiments. In some embodiments, the front side distance D3 is larger than about 15 μm, so as to meet advanced BEOL/MEOL routing requirements. In some embodiments, a backside distance D4 measured from the power input pads 314P to the active component 204 is in a range from about 4 μm to about 10 μm. In some embodiments, the backside distance D4 is large enough to accommodate the minimum thickness of the second semiconductor die 200, such as greater than about 3 μm. In some embodiments, the backside distance D4 is shorter than the front side distance D3. For example, the backside distance D4 is shorter than about 10 μm.

Similar to the semiconductor device 110 with a power delivery, the parasitic losses between the point of load (i.e., the active component 204) in the first semiconductor die 200′ may increase when the distance D1′ between the first semiconductor die 200′ and the second semiconductor die 300 that comprises the passive circuit 306 increases. In some embodiments, the distance D1′ is in a range from about 1 μm to about 5 μm. The minimum of the distance D1′ is larger than 1 μm for space of substrate 202 which is thinned down, the insulating layer 214 and the insulating layer 308. The maximum distance of D1′ is less than 5 μm to shorten the distance of power supply outputted from the passive circuit 306 of the second semiconductor die 300 to the active components 204 of the first semiconductor die 200′. Compared to the configuration of the semiconductor device 110 shown in FIG. 2, the distance D1′ can be reduced since the passive circuit 306 integrated in the second semiconductor die 300 is bonded to the backside of the first semiconductor die 200, and the distance contributed by the thickness of the BEOL layer 208 can be excluded from the distance D1′. As a result, the power delivery performance of the semiconductor device 110a can be improved.

Comparing the embodiment in FIG. 4 with the embodiment in FIG. 2, the RDL structure 210 in FIG. 2 may be removed. The power transmission and signal transmission can be implemented by the TSV formed in the substrate 202, the signal bonding pads 216S and the power bonding pads 216P. Therefore, the overall process cost of the semiconductor device 110 can be reduced. This, however, should not be considered as a limitation. In some embodiments, the extra RDL structure can be formed between the substrate 202 and the insulating layer 214. The extra RDL structure can reduce the routing complexity of power transmission and signal transmission.

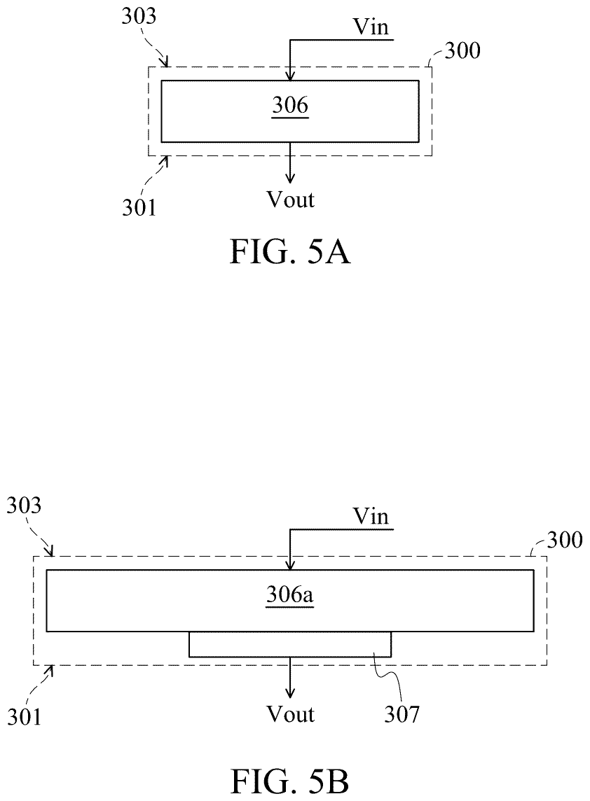

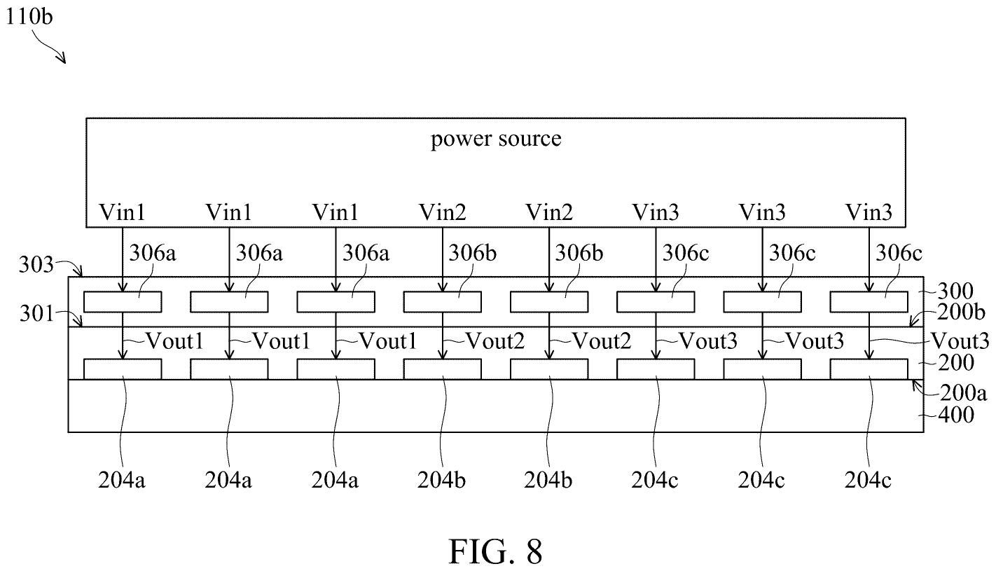

FIG. 5A is a schematic block diagram illustrating a passive circuit 306 in a semiconductor die 300 shown in FIG. 4, in accordance with some embodiments. As shown in FIG. 5A, the passive circuit 306 is embedded or integrated in the semiconductor die 300. The passive circuit 306 may contain passive components (not shown), such as capacitors or inductors. The passive circuit 306 is configured to receive an input power from a power source (as shown in FIG. 8) and regulate or covert a power delivery provided through the second side of the semiconductor die 300. In other words, the passive circuit 306 is configured to receive a first voltage (i.e., input voltage, Vin) from the power source and then provide a second voltage (i.e., output voltage, Vout) to the active component(s) 204 (not shown). In some embodiments, the first voltage is different than the second voltage. For example, the first voltage (Vin) is higher or lower than the second voltage (Vout). In some embodiments, the passive circuit 306 is free of any inductors. In those cases, values of the first voltage (Vin) and the second voltage (Vout) are integers. For example, the ratio of the first voltage to the second voltage (Vin:Vout) may be 2:1, 3:1, 3:2, 4:1, 4:3, 5:1, 5:2, 5:3, 5:4 etc. In some other embodiments, values of the first voltage (Vin) and the second voltage (Vout) are not integers, and the ratio of the first voltage (Vin) to the second voltage (Vout) is an substantially irreducible fraction (or a fraction in simplest form) after the ratio is reduced. For example but not limited to, the first voltage may be 5.4 volts and the second voltage may be 1.8 or 3.6 volts. Therefore, the irreducible fraction of the reduced ratio of the first voltage to the second voltage is 3:1 or 3:2.

In some embodiments, the passive circuit 306 may comprise the passive components, such as capacitors or inductors, and the active components, such as transistors used to control the aforementioned passive components. The active components within the passive circuit 306 are configured to control the operation of the passive components within the passive circuit 306, which are different from the active components 204 in the first semiconductor die 200′. In some embodiments, the active components 204 of the first semiconductor die 200′ are used to perform the high-performance computing, so the process node of the active components 204 of the first semiconductor die 200′ has a more advanced process node compared to the active components (not shown) that control the passive components in the second semiconductor die 300.

In some embodiments, the passive circuit 306 comprises capacitors as the passive components and the transistors used to control the passive components. The capacitance in the unit area of the passive circuit 306 is at least 10 times or larger than the capacitance in the unit area of the first semiconductor die 200′, which may use embedded capacitors, such as MIM or MIS capacitors. In some embodiments, the capacitance in the unit area of the passive circuit 306 can exceed 1 nF/mm². In some embodiments, the occupied area ratio between the passive components and the active components in the second semiconductor die 300 is larger than the occupied area ratio between the passive components and the active components in the first semiconductor die 200′. The calculation of the area ratio does not include the parasitic passive components.

In some other embodiments, the passive circuit 306 in the semiconductor die 300 shown in FIG. 4 can be replaced by a first passive circuit 306a and a second passive component 307 (which contains thin film inductors) formed over one side of the first passive circuit 306a, as shown in FIG. 5B. The first passive circuit 306a comprises one or more passive components (such as capacitors, not shown) and one or more active components (such as transistors, not shown) electrically coupled to the passive component. Moreover, the thin film inductors are made of magnetic materials. The first passive circuit 306a and the second passive component 307 can function as a power conversion circuit. In some embodiments, the second passive component 307, such as the thin film inductors made of magnetic materials, is formed by additional deposition process and patterning process comparing with formation of the passive circuit 306a.

Similar to the passive circuit 306 shown in FIG. 5A, the first passive circuit 306a and the second passive component 307 shown in FIG. 5B are configured to receive a first voltage (i.e., input voltage, Vin) from a power source (not shown) and then provide a second voltage (i.e., output voltage, Vout) to the active component(s) 204 (not shown). In some embodiments, the first voltage is different than the second voltage. For example, the first voltage (Vin) is higher or lower than the second voltage (Vout). In FIG. 5B, the power conversion circuit with the thin film inductor can perform precise voltage adjustment during the voltage conversion.

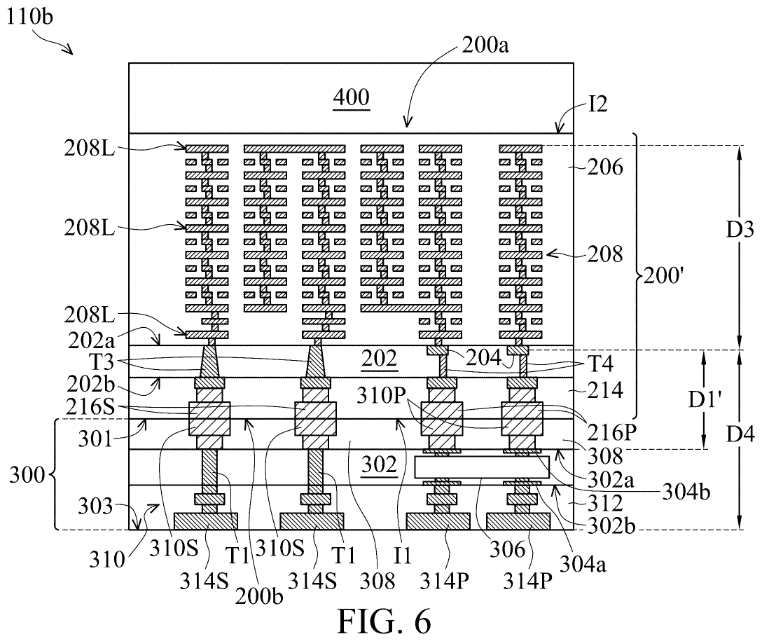

FIG. 6 is a cross-sectional view of a semiconductor device 110b with a power delivery in accordance with some embodiments. Elements in FIG. 6 that are the same as those in FIG. 4 are labeled with the same reference numbers as in FIG. 4 and may not be described again. In some embodiments, the semiconductor device 110c shown in FIG. 6 is similar to the semiconductor device 110a shown in FIG. 4. However, unlike the semiconductor device 110a, the power source (not shown) can provide a voltage from the power input pads 102P of the package substrate 100 (as shown in FIG. 3) to the first semiconductor die 200′ via the second conductive connectors 104P (as shown in FIG. 3), the power input pads 314P and a first metal routing 304a in the second semiconductor die 300, the passive circuit 306 and a second metal routing 304b in the second semiconductor die 300, and the power bonding pads 310P in the second semiconductor die 300. Therefore, the voltage provided by the power source is transmitted by metal-via routing (e.g., the first metal routing 304a and the second metal routing 304b) from power source, through the passive circuit 306, to the power of load. The interconnects in the second semiconductor die 300 for signal transmission and power transmission are different. The signals are transmitted through TSV (e.g., TSVs T1) directly for high speed, and the power are transmitted through metal-via routing (e.g., the first metal routing 304a and the second metal routing 304b) for the purpose of connection between the passive components within the passive circuit 306, such as capacitors or inductors, and the active components within the passive circuit 306, such as the transistors configured to control the capacitors or inductor.

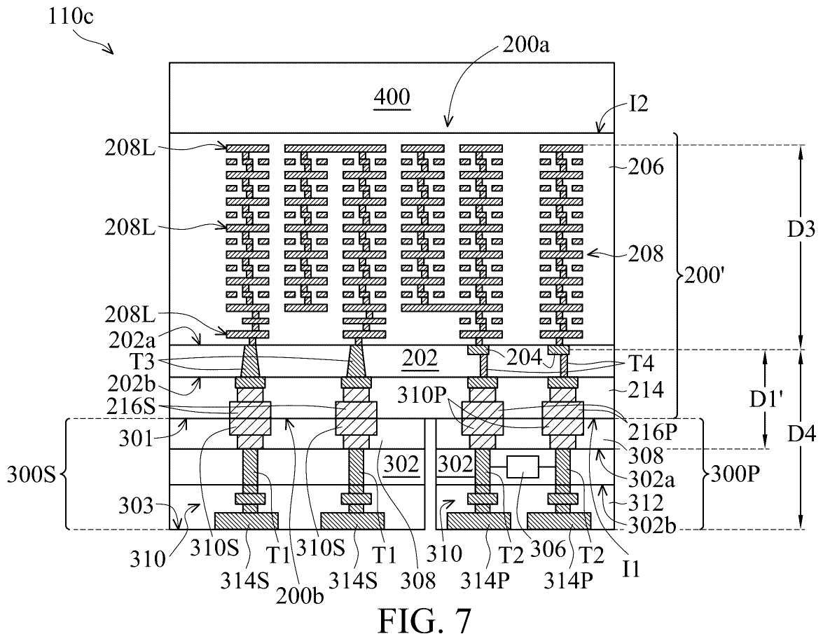

FIG. 7 is a cross-sectional view of a semiconductor device 110c with a power delivery in accordance with some embodiments. Elements in FIG. 7 that are the same as those in FIG. 4 are labeled with the same reference numbers as in FIG. 4 and may not be described again. In some embodiments, the semiconductor device 110c shown in FIG. 7 is similar to the semiconductor device 110a shown in FIG. 4. However, unlike the semiconductor device 110a, the power source (not shown) can provide a voltage from the power input pads 102P of the package substrate 100 (as shown in FIG. 3) to the first semiconductor die 200′ via the second conductive connectors 104P and the power input pads 314P, the passive circuit 306 and TSVs T2, and the power bonding pads 310P in a semiconductor die 300P. In addition, the signals are transmitted through TSVs T1 between the signal input/output pads 102S of the package substrate 100 (as shown in FIG. 3) to the first semiconductor die 200′ via the first conductive connectors 104S and the signal input/output pads 314S, the passive circuit 306 and TSVs T1, and the signal bonding pads 310S in another semiconductor die 300S. In some embodiments, the semiconductor dies 300P and 300S have a size smaller than the second semiconductor die 300 shown in FIGS. 3 and 4. Moreover, the top side surfaces of the semiconductor dies 300P and 300S are substantially level with each other and the bottom side surfaces of the semiconductor dies 300P and 300S are substantially level with each other. In some embodiments, the semiconductor die 300P is electrically connected to the power delivery pads only, and is referred to as a voltage regulator die or voltage converter die (or an integrated passive device (IPD) die) to manage the power delivery to the first semiconductor die 200′. In some embodiments, the semiconductor die 300S has TSVs (e.g., TSVs T1) formed therein only and without any circuits therein, and is referred to as a supporting die that may be made of silicon. In those cases, the size of the bottom semiconductor die is not limited to be substantially same as the size of the top semiconductor die. Moreover, other regions for signal connection can be replaced by the supporting die with TSVs. However, it is not limited thereto. In some other embodiments, the semiconductor die 300S may comprise TSVs (e.g., TSVs T1) and extra functional circuits to further control or modulate the signals from the semiconductor die 200′ then transmit the processed signals to the signal bonding pads 310S.

FIG. 8 is a schematic block diagram illustrating a semiconductor device 110b with a power delivery in accordance with some embodiments. Elements in FIG. 8 that are the same as those in FIGS. 3 and 4 are labeled with the same reference numbers as in FIGS. 3 and 4 and may not be described again. In some embodiments, the semiconductor device 110b shown in FIG. 8 is similar to the semiconductor device 110a shown in FIGS. 3 and 4. More specifically, the semiconductor device 110b comprises a first semiconductor die 200, a second semiconductor die 300 stacked below the first semiconductor die 200 and a capping substrate 400 stacked above the first semiconductor die 200. Moreover, the front side 200a of the first semiconductor die 200 is bonded to the capping substrate 400 and the backside 200b of the first semiconductor die 200 is bonded to the first side 301 of the second semiconductor die 300.

In some embodiments, the first semiconductor die 200 in the semiconductor device 110b comprises at least two groups of processing units disposed therein. For example, the first semiconductor die 200 may comprise a first group of processing units (e.g., three processing units 204a), a second group of processing units (e.g., two processing units 204b), and a third group of processing units (e.g., three processing units 204c), as shown in FIG. 6.

In some embodiments, each of the processing units 204a, 204b, and 204c comprises one or more active components 204 (which are shown in FIG. 3), such as transistors. Moreover, the processing units 204a, 204b, and 204c may receive output voltages different to each other from the second semiconductor die 300. More specifically, each of the processing units 204a receives a first output voltage (Vout1), each of the processing units 204b receives a second output voltage (Vout2) that is different than the first output voltage (Vout1), and each of the processing units 204c receives a third output voltage (Vout3) that is different than the first output voltage (Vout1) and the second output voltage (Vout2).

However, it is appreciated that the number of groups of the processing units and the number of the processing units in the corresponding group depend on the design demands, and are not limited to the exemplary embodiments shown in FIG. 6.

Moreover, the second semiconductor die 300 in the semiconductor device 110b comprises at least two groups of power conversion units disposed therein. One of the groups of power conversion units correspondingly and electrically coupled to one of the groups of processing units. For an example, the second semiconductor die 300 may comprise a first group of power conversion units (e.g., three power conversion units 306a), a second group of power conversion units (e.g., two power conversion units 306b), and a third group of power conversion units (e.g., three power conversion 306c), as shown in FIG. 6.

In some embodiments, each of the power conversion units 306a, 306b, and 306c comprises active components (e.g., transistors) and passive component (e.g., cylinder-type or crown-type capacitors, or thin film inductor). Moreover, each of the power conversion units 306a, 306b, and 306c receives an input voltage from a power source (not shown) that is electrically coupled to the second side 303 of the second semiconductor die 300. For example, each of the power conversion 306a receives a first input voltage (Vin1), each of the power conversion 306b receives a second input voltage (Vin2), and each of the power conversion 306c receives a third input voltage (Vin3). In some embodiments, the first input voltage (Vin1) is substantially the same (within +/−10% variation) as the second input voltage (Vin2) and the third input voltage (Vin3). In other words, the first input voltage, the second input voltage and the third input voltage share the same input voltage. Thereafter, each of the power conversion units 306a, 306b, and 306c provides an output voltage to the corresponding processing unit in the first semiconductor die 200. In some embodiments, the output voltage is lower than the input voltage. In present embodiment, the power conversion units 306a, 306b and 306c are integrated into one second semiconductor die 300. The integration of several power conversion units into one second semiconductor die 300 can provide lower cost for fabrication and higher flexibility in output voltages.

In such a configuration of the semiconductor device 110b, different output voltages can be provided to different processing units through different power conversion units. As a result, different output voltage domains can be more easily controlled.

According to the foregoing embodiment, the semiconductor device comprises a bottom semiconductor die that is integrated with a passive circuit or a power conversion circuit and a top semiconductor die receiving the power source through and bonded to the bottom semiconductor die. Therefore, the distance from the power source to the top semiconductor die can be reduced, thereby reducing the parasitic losses between the point of load in the top semiconductor die and the passive circuit/power conversion circuit in the bottom semiconductor die. Moreover, since the bottom semiconductor die is bonded to the backside (which is opposite to the active side) of the top semiconductor die, the power source can be delivered to the point of load in the top semiconductor die through a minimal distance. As a result, the parasitic losses can be reduced further, and the power delivery performance can be improved further. According to the foregoing embodiment, since different processing units (point of loads) can receive different output voltages (provided by different power conversion units), different output voltage domains can be more easily controlled. Moreover, since the input voltage (provided by the power source) can be shared by different voltage conversion units, so the input voltage can be delivered under a high voltage condition. Therefore, the current of the input power can be reduced. As a result, parasitic IR drop can be reduced or mitigated, and the power consumption will also be reduced.

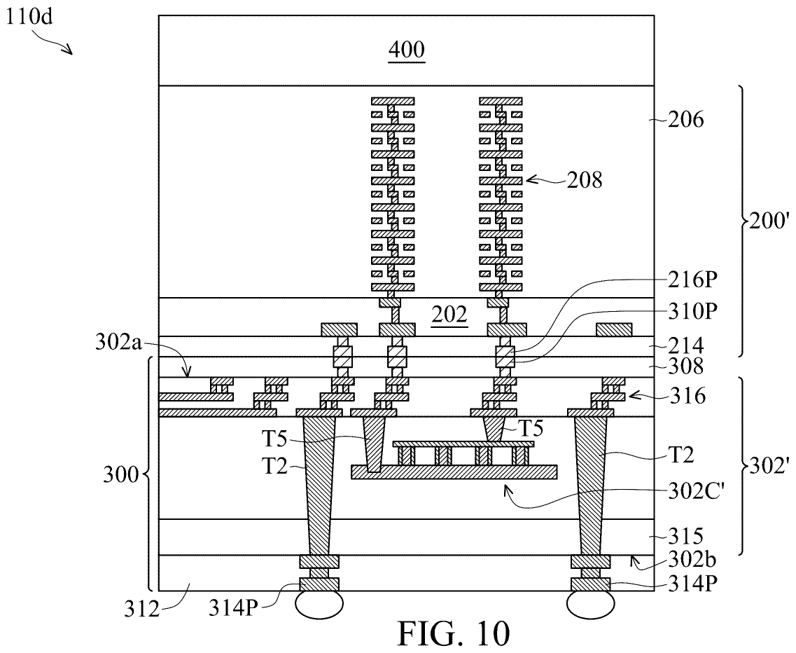

In some embodiments, the different process sequence can be performed. FIG. 10 is a cross-sectional view of a semiconductor device 110d with a power delivery in accordance with some embodiments. Elements in FIG. 10 that are similar to those in FIGS. 3 and 4 are labeled with the same reference numbers as in FIGS. 3 and 4 and may not be described again. In FIG. 10, the TSVs T2 for connecting power input pads 314P are formed before the bonding process. In this embodiment, the elements related to the power delivery are depicted and the other elements are omitted. The second semiconductor die 300 comprises the passive circuit 302′, and the passive circuit 302′ includes the 3D cylinder-type or crown type capacitor 302C′, which can use the aforementioned structures described in the FIG. 9A or 9B. In this embodiment, the second semiconductor die 300 comprises a routing layer 316, which is an RDL layer or the Back-End-Of-Line (BEOL) of the second semiconductor die 200′, electrically coupled to the 3D cylinder-type or crown type capacitors 306C′. The TSVs T2 are formed during the fabrication of the second semiconductor die 300 and electrically coupled to the routing layer 316. After the bonding process between the first semiconductor die 200′ and the second semiconductor die 300 through the power bonding pads 216P and 310P, the substrate 315 of the second semiconductor die 300 is thinned down from the second surface 302b of the second semiconductor die 300 to expose the formed TSVs T2. After that, the insulating layer 312 is formed to cover the second surface 302b, and the power input pads 314P are formed in the insulating layer 312 and electrically coupled to the TSVs T2. In this embodiment, the TSVs T2 are formed before the bonding processes and revealed after the bonding processes. In some embodiments, each of the TSVs T2 has tapered sidewalls, although vertical sidewalls may be implemented. For example, each of the TSVs T2 has a first end proximal to the first semiconductor die 200′ and a second end distal to the first semiconductor die 200′. In each of the TSVs T2, the first end has a larger width than that of the second end.

More specifically, in some embodiments, the second semiconductor die 300 further comprises additional TSVs T5 electrically couple the 3D cylinder-type or crown type capacitor 302C′. The additional TSVs T5 form within the passive circuit 302′ and electrically couple the top electrode and the bottom electrode of the 3D cylinder-type or crown type capacitor 302C′. In some embodiments, the additional TSVs T5 have a shorter length than a length of the TSVs T2 along a vertical direction. In some embodiments, the additional TSVs T5 electrically couple the TSVs T2 by the routing layer 316.

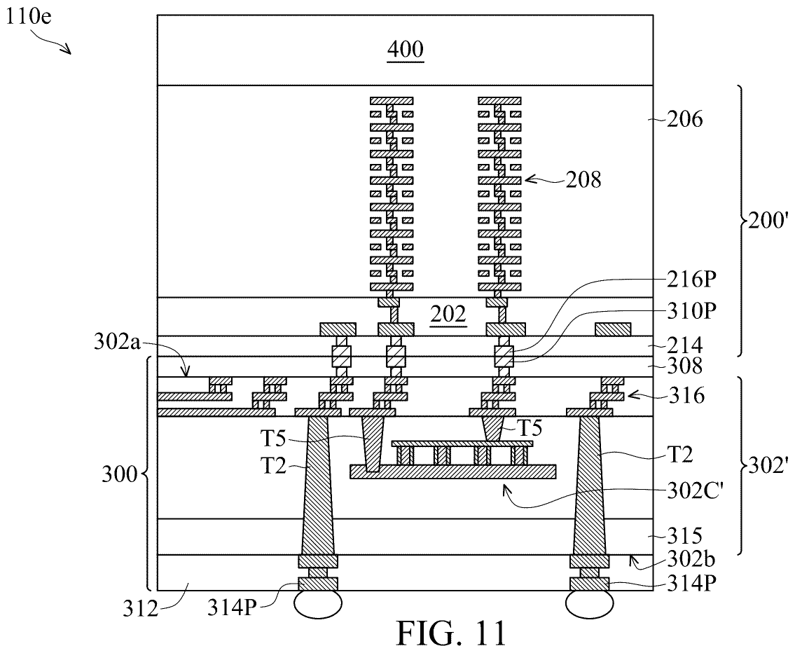

FIG. 11 is a cross-sectional view of a semiconductor device 110e with a power delivery in accordance with some embodiments. Elements in FIG. 11 that are similar to those in FIGS. 3 and 4 are labeled with the same reference numbers as in FIGS. 3 and 4 and may not be described again. In the embodiment of FIG. 11, the structure is substantially similar with the embodiment in FIG. 10 except for the reversed tapered shape of the TSVs T2. In this embodiment, the TSVs T2 are formed after the bonding process for bonding the first semiconductor die 200′ and the second semiconductor die 300. After the bonding process, the substrate 315 of the second semiconductor die 300 is thinned down from the second surface 302b. The TSVs T2 are then formed in the second semiconductor die 300, with extending through the substrate 315 to electrically couple the routing layer 316. The TSVs T2 may have a top surface coplanar with the surface 302b of the substrate 315 away from the first semiconductor die 200′. In some embodiments, an insulating layer 312 is formed to cover the second surface 302b of second semiconductor die 300, the power input pads 314P are formed in the insulating layer 312 and electrically coupled to the TSVs T2. In this embodiment, the TSVs T2 are formed after the bonding processes. The TSVs T2 have a reversed tapered shape as well. For example, a first end of the TSV T2 proximal to the first semiconductor die 200′ has a width smaller than that of a second end of the TSV T2 distal to the first semiconductor die 200′.

While the present application has been described by way of example and in terms of the preferred embodiments, it should be understood that the present application is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a first semiconductor die having a front side and a backside opposite to the front side, wherein the first semiconductor die comprises a plurality of first active components disposed adjacent to the front side of the first semiconductor die; and
a second semiconductor die having a first side bonded to the backside of the first semiconductor die and a second side opposite to the first side, wherein the second semiconductor die comprises a plurality of passive components that are configured to manage a power delivery to the first semiconductor die.

2. The semiconductor device as claimed in claim 1, wherein the plurality of passive components is configured to receive an input power from a power source and regulate or covert the power delivery provided through the second side of the second semiconductor die.

3. The semiconductor device as claimed in claim 2, wherein the first semiconductor die comprises:
a substrate having a front side surface and a backside surface corresponding to the front side and the backside of the first semiconductor die, respectively, wherein the plurality of first active components is formed adjacent to the front side surface;
a first insulating layer formed over the backside surface; and
a first power bonding pad formed in the first insulating layer, wherein the first power bonding pad is configured to receive the power delivery that has been regulated or converted by the plurality of the passive components.

4. The semiconductor device as claimed in claim 3, wherein the first semiconductor die further comprises:
a second insulating layer formed over the front side surface of the substrate; and
a multi-layer interconnect structure formed in the second insulating layer, wherein the multi-layer interconnect structure comprises a plurality of metal layers.

5. The semiconductor device as claimed in claim 4, further comprising:
a capping substrate covering a top of the second insulating layer, wherein the capping substrate is free of active components, passive components, and conductors.

6. The semiconductor device as claimed in claim 4, wherein the second semiconductor die comprises:
a device layer having a first surface and a second surface corresponding to the first side and the second side of the second semiconductor die, respectively;
a third insulating layer formed over the first surface of the device layer and in direct contact with the first insulating layer;
a second power bonding pad formed in the third insulating layer and in direct contact with the first power bonding pad, wherein the second power pad is configured to receive the power delivery that has been converted by the plurality of the passive components; and
a power input pad formed over the second surface of the device layer and is configured to receive the input power, wherein a thickness of the power input pad is greater than a thickness of each one of the plurality of metal layers of the multi-layer interconnect structure.

7. The semiconductor device as claimed in claim 6,
wherein the first semiconductor die further comprises a first signal bonding pad formed in the first insulating layer; and
wherein the second semiconductor die further comprises a second signal bonding pad formed in the third insulating layer and in direct contact with the first signal bonding pad, and a signal input/output pad formed over the second surface of the device layer and electrically coupled to a signal source.

8. The semiconductor device as claimed in claim 1, wherein the plurality of passive components comprises 3D cylinder-type or crown-type capacitors.

9. The semiconductor device as claimed in claim 1, wherein the second semiconductor die further comprises second active components electrically coupled to the plurality of passive components.

10. The semiconductor device as claimed in claim 9, further comprising:
a plurality of thin film inductors formed over the second side of the second semiconductor die and made of magnetic materials.

11. The semiconductor device as claimed in claim 1, wherein the plurality of passive components comprises inductors.

12. The semiconductor device as claimed in claim 1, wherein a distance between one of the plurality of first active components to the second semiconductor die is in a range from about 1 μm to about 5 μm.

13. The semiconductor device as claimed in claim 6, wherein a distance between one of the plurality of first active components to the power input pads to the is in a range from about 4 μm to about 10 μm.

14. A semiconductor device, comprising:
a first semiconductor die having a front side and a backside opposite to the front side, the first semiconductor die comprising a first processing unit and a second processing unit adjacent to the front side; and
a second semiconductor die having a first side bonded to the first semiconductor die and a second side opposite to the first side, the second semiconductor die comprising a first power conversion unit and a second power conversion unit,
wherein the first power conversion unit and the second power conversion unit are configured to respectively receive a first input voltage and a second input voltage from the second side of the second semiconductor die and respectively provide a first output voltage to the first processing unit and a second output voltage to the second processing unit.

15. The semiconductor device as claimed in claim 14, wherein the first power conversion unit and the second power conversion unit are configured to receive the first input voltage and the second input voltage from a power source, and the first input voltage is substantially the same as the second input voltage.

16. A semiconductor package, comprising:
a package substrate comprising a power input pad and a signal input/output pad formed on a top surface of the substrate;
a first conductive connector and a second conductive connector electrically coupled to the power input pad and the signal input/output pad, respectively; and
a stack structure, comprising:
a top semiconductor die comprising a plurality of first transistors therein and having a front side and a backside opposite to the front side; and
a bottom semiconductor die comprising a plurality of passive components therein and having a first side bonded to the backside of the top semiconductor die and a second side opposite to the first side and electrically coupled to the power input pad of the package substrate via the first conductive connector.

17. The semiconductor package as claimed in claim 16, wherein the bottom semiconductor die is electrically coupled to the signal input/output pad of the package substrate, and the bottom semiconductor die further comprises:
a semiconductor substrate; and
a first through-substrate via (TSV) and a second TSV formed in the semiconductor substrate and electrically coupled to the first conductive connector and the second conductive connector, respectively.

18. The semiconductor package as claimed in claim 17, wherein the first TSV is configured to receive a signal source provided from the top semiconductor die or the substrate and the second TSV is configured to receive a power source provided from the power input pad of the substrate.

19. The semiconductor package as claimed in claim 17, wherein each of the first TSV and the second TSV comprises a first end proximal to the top semiconductor die having a first size and a second end distal to the top semiconductor die having a second size different from the first size.

20. The semiconductor package as claimed in claim 16, further comprising a supporting die substantially level with the bottom semiconductor die and bonded to the backside of the top semiconductor die, wherein the supporting die is electrically coupled to the signal input/output pad of the package substrate via the second conductive connector.
